(19) United States
(12) Patent Application Publication
(10) Pub. No.: US 2020/0335606 A1
(43) Pub. Date: Oct. 22, 2020

(54) VERTICAL TUNNELING FIELD-EFFECT TRANSISTOR AND METHOD OF FABRICATING THE SAME

(71) Applicant: IUCF-HYU (INDUSTRY-UNIVERSITY COOPERATION FOUNDATION HANYANG UNIVERSITY), Seoul (KR)

(72) Inventors: Tae Whan KIM, Seoul (KR); Joon Sung AHN, Seoul (KR); Jun Gyu LEE, Daegu (KR)

(73) Assignee: IUCF-HYU (INDUSTRY-UNIVERSITY COOPERATION FOUNDATION HANYANG UNIVERSITY), Seoul (KR)

(21) Appl. No.: 16/303,714

(22) PCT Filed: Aug. 22, 2017
(86) PCT No.: PCT/KR2017/009168

§ 371 Date: Nov. 21, 2018

(30) Foreign Application Priority Data
Aug. 22, 2016 (KR) 10-2016-0106351

(51) Int. Cl. H01L 29/66; H01L 29/423; H01L 29/73; H01L 29/78

(52) U.S. Cl. CPC H01L 29/66666; H01L 29/42392; H01L 29/7849; H01L 29/7827; H01L 29/7311

(57) ABSTRACT

A vertical tunneling field-effect transistor (TFET) and a method of fabricating the same are provided. More particularly, the vertical TFET includes a source layer that is disposed on a substrate, has a protrusion portion extending upwardly, and is doped at a uniform concentration in an entire region thereof including the protrusion portion, a channel pattern that covers the protrusion portion of the source layer on the source layer and exposes the remainder of the source layer, a drain pattern that overlaps the channel pattern on the channel pattern and is doped to have a concentration gradient, a gate insulating film that covers the source layer, the channel pattern, and the drain pattern, and a gate electrode that is disposed around the channel pattern on the gate insulating film.

### TECHNICAL FIELD

The present invention relates to a vertical tunneling field-effect transistor (TFET) and a method of fabricating the same, and more specifically, to a vertical TFET capable of improving electrical properties and a method of fabricating the same.

### BACKGROUND ART

Until a recent date, highly integrated circuits could be fabricated by reducing the size of metal oxide semiconductor field-effect transistors (MOSFETs) in semiconductor industries. However, when the size of MOSFETs is further reduced to be a certain level or lower in order to microminiaturize semiconductor devices, there are problems that the leakage current is increased, the breakdown voltage is reduced, and the short channel effect becomes strong. To solve these problems, multi-gate structures, high-dielectric gate techniques, and the like have been attempted. However, there is still a problem that the power consumption of MOSFETs is rapidly increased.

Accordingly, research on tunnel field-effect transistors (TFETs) using band-to-band tunneling (BTBT), which is a quantum mechanical phenomenon, has recently attracted attention.

It is impossible that in conventional MOSFETs, the slope of a threshold voltage at room temperature is reduced below 60 mV/dec by thermionic emission, whereas TFETs have an advantage that the output current can be changed by a subtle change of an input voltage since the flow of current is controlled in a tunneling manner other than thermionic emission.

However, TFETs have still problems that the TFETs are difficult to apply to actual devices because of the significantly lower drive current (on current) compared to MOSFETs and that the leakage current is increased by ambipolar current, which is a unique phenomenon of the TFETs.

In this regard, in order to increase the low drive current of the TFETs, a heterojunction TFET for replacing a p+ region or n+ region with other materials has been developed, but there is a problem that the complexity and cost of the process increase. Further, to prevent the ambipolar current of TFETs, improved techniques using structural separation have been attempted, but there is a limitation that the area loss due to the separation is great in applying the techniques to actual processes.

### DISCLOSURE

### Technical Problem

The present invention is directed to providing a vertical tunneling field-effect transistor (TFET) capable of reducing an occurrence of ambipolar current while increasing the drive current of a device and a method of fabricating the same.

### Technical Solution

One aspect of the present invention provides a vertical tunneling field-effect transistor (TFET). The vertical TFET includes: a source layer that is disposed on a substrate, has a protrusion portion extending upwardly, and is doped at a uniform concentration in an entire region thereof including the protrusion portion; a channel pattern that covers the protrusion portion of the source layer on the source layer and exposes the remainder of the source layer; a drain pattern that overlaps the channel pattern on the channel pattern and is doped to have a concentration gradient; a gate insulating film that covers the source layer, the channel pattern, and the drain pattern; and a gate electrode that is disposed around the channel pattern on the gate insulating film.

A junction between the protrusion portion of the source layer and the channel pattern may be an abrupt junction, and a junction between the channel pattern and the drain pattern may be a graded junction.

The protrusion portion may have a three-dimensional shape that increases a contact area of the source layer with respect to the channel pattern.

The three-dimensional shape may include a columnar shape, a horn shape, a hemispherical shape, or combinations thereof.

A height of the gate electrode may be the same as that of the channel pattern.

The gate electrode may be disposed in a double gate, triple gate, or gate-all-around structure around the channel pattern.

The protrusion portion may include a plurality of protrusion shapes that protrude upwardly from the source layer.

Another aspect of the present invention provides a method of fabricating a vertical TFET. The method includes: epitaxially growing a source layer to a first thickness on a substrate; forming, on the source layer, a protrusion portion protruding upwardly by etching the source layer to a second thickness less than the first thickness; forming a channel pattern that covers the protrusion portion and a drain pattern that is ion-implanted into an upper region of the channel pattern, on the source layer in which the protrusion portion is formed; forming a gate insulating film to cover the source layer, the channel pattern, and the drain pattern; and forming a gate electrode on the gate insulating film to be disposed around the channel pattern.

The epitaxially growing of the source layer may include doping the source layer with impurities at a uniform concentration.

The source layer may be epitaxially grown by vapor phase epitaxy, liquid phase epitaxy, or molecular beam epitaxy.

The forming of the channel pattern and the drain pattern may include: forming a channel layer on the source layer to cover the protrusion portion; forming a drain layer by injecting impurities into an upper region of the channel layer by an ion implantation method, and etching the channel layer and the drain layer such that the protrusion portion is covered.

The forming of the channel pattern and the drain pattern may include: forming a channel layer on the source layer to cover the protrusion portion; forming the channel pattern by etching the channel layer such that the protrusion portion is covered; and forming the drain pattern by ion-implanting impurities into the upper region of the channel pattern using a doping mask.

The drain pattern may be doped with impurities by the ion-implanting to have a concentration gradient.

The forming of the protrusion portion may include etching the remainder of the source layer except for a portion thereof to the second thickness using an etching mask.

### Advantageous Effects

According to the present invention, by epitaxially growing a source region, doping the source region with impurities at a uniform concentration, and forming an abrupt junction between the source region and a channel region, the width of a potential barrier between the source region and the channel region can be greatly reduced during a driving operation (on operation) of a TFET, thereby increasing an amount of electrons tunneled and increasing the drive current of the TFET.

Further, by forming the source region as a three-dimensional structure having a protrusion portion through etching the source region, an area in which tunneling occurs can be increased. Accordingly, a tunneling phenomenon in other directions as well as an epitaxial growth direction additionally occurs, thereby being capable of increasing the drive current of the TFET.

Moreover, by forming, by ion-implanting, a drain region doped with a gentle concentration gradient and forming a graded junction between the drain region and the channel region, the width of a potential barrier between the drain region and the channel region can be relatively widened. Accordingly, the ambipolar leakage current due to a gate voltage during an on or off operation of the TFET can be reduced.

Meanwhile, the effects of the present invention are not limited to the above-mentioned effects, and other effects unmentioned could be clearly understood by a person skilled in the art from the following descriptions.

### DESCRIPTION OF DRAWINGS

FIG. 1 is a cross-sectional view illustrating a vertical tunneling field-effect transistor (TFET) according to an embodiment of the present invention.

FIG. 2 is a graph illustrating a doping concentration of impurities taken along line S-S′ of FIG. 1.

FIG. 3 is a cross-sectional view illustrating an operating principle of the vertical TFET according to an embodiment of the present invention.

FIGS. 4A and 4B are graphs illustrating an energy band diagram and tunneling current from a source region of FIG. 3.

FIG. 5 is a cross-sectional view of a vertical TFET according to another embodiment of the present invention.

FIGS. 6A to 6I are cross-sectional views illustrating a method of fabricating a vertical TFET according to an embodiment of the present invention.

FIGS. 7A to 7H are cross-sectional views illustrating a method of fabricating a vertical TFET according to another embodiment of the present invention.

### MODES OF THE INVENTION

Hereinafter, exemplary embodiments of the present invention will be described in more detail with reference to the accompanying drawings, in order to describe the present invention more particularly. However, the present invention is not limited to the embodiments described herein but may be embodied in other forms.

In the drawings, the thicknesses of layers and regions may be exaggerated or reduced for clarity. Like reference numerals denote like elements throughout the specification.

Vertical Tunneling Field-Effect Transistor (TFET)

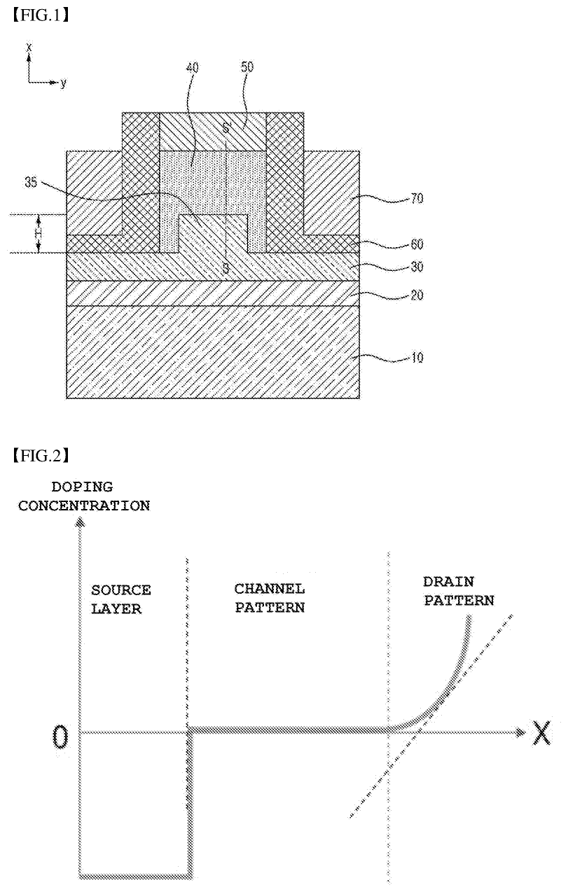

FIG. 1 is a cross-sectional view illustrating a vertical TFET according to an embodiment of the present invention.

Referring to FIG. 1, a vertical TFET according to the present embodiment includes a substrate 10, a source layer 30, a channel pattern 40, a drain pattern 50, a gate insulating film 60, and a gate electrode 70. The TFET may further include a buried oxide layer 20 disposed between the substrate 10 and the source layer 30.

The substrate 10 as an insulating substrate may include, for example, a silicon material. The substrate 10 may be, for example, a silicon-on-insulator (SOI) substrate, a single crystal silicon substrate, a polycrystalline silicon substrate, a glass substrate, a sapphire substrate, a polymer substrate, or the like but is not limited thereto.

The buried oxide layer 20 may be disposed on the substrate 10. The buried oxide layer 20 may separate the substrate 10 and constituent elements disposed thereon and protect an operating region of the TFET from defects such as oxygen ions or metal ions.

The source layer 30 is disposed on the substrate 10 and has a protrusion portion 35 that protrudes at a certain height H. The source layer 30 is doped with impurities at a uniform concentration in an entire region thereof that includes the protrusion portion 35. To this end, the source layer 30 may be formed by epitaxial growth on the substrate 10 (or the buried oxide layer 20). At this time, the source layer 30 may be epitaxially grown in a direction X perpendicular to the substrate 10. The source layer 30 contains impurities, and a concentration at which the impurities are doped by epitaxial growth may be substantially uniform in the entire region of the source layer 30.

The protrusion portion 35 of the source layer 30 may be a portion that protrudes from a surface of a layer-like structure of the source layer 30 and may contain the impurities doped at the uniform concentration as in the layer-like structure of the source layer 30. The protrusion portion 35 may be formed by at least partially etching the epitaxially grown source layer 30.

The protrusion portion 35 may have a three-dimensional shape that increases a contact area between the source layer 30 and the channel pattern 40. For example, the protrusion portion 35 may include a columnar shape, a horn shape, a hemispherical shape, or combinations thereof but is not limited thereto. As the source layer 30 has the protrusion portion 35 of the three-dimensional shape, the contact area between the source layer 30 and the channel pattern 40 is increased than an area in which the source layer 30 having no protrusion portion 35 is in contact with the channel pattern 40. Thus, a tunneling phenomenon may occur in the direction X perpendicular to the substrate, a direction Y parallel to the substrate, or combinations thereof from a source region that has the protrusion portion 35 of the three-dimensional shape. Thus, the drive current of the TFET may be increased.

The channel pattern 40 may be disposed on the source layer 30 and cover the protrusion portion 35 of the source layer 30. In detail, the channel pattern 40 may be at least partially in contact with side surfaces and an upper surface of the protrusion portion 35 that protrudes from the source layer 30. FIG. 1 illustrates that the protrusion portion 35 has a columnar shape and side surfaces and an upper surface of the columnar shape are entirely in contact with the channel pattern 40. However, even when the protrusion portion 35 has any other three-dimensional shape other than the columnar shape, the channel pattern 40 may cover the protrusion portion 35 to surround the protrusion portion 35. The channel pattern 40 may further cover a portion of the layer-like structure of the source layer 30 around the protrusion portion 35. The remainder of the source layer 30 not covered by the channel pattern 40 is covered by the gate insulating film 60 that is described later.

The channel pattern 40 may include a Group IV semiconductor or a Group III-V compound semiconductor. For example, the channel pattern 40 may include, as a Group IV semiconductor, Si, Ge, or the like or may include, as a Group III-V compound semiconductor, InAs, InP, GaAs, GaN, InSb, GaSb, AlSb, AGaAs, InGaAs, InGaN, AlGaN, GaNAs, InAsSb, GaAsSb, InGaSb, AlnSb, InGaAlN, AlInGaP, InGaAsP, GaInAsN, InGaAlSb, InGaAsSb, AlInGaPSb, and the like which include In, As, P, Ga, N, or Sb.

FIG. 2 is a graph illustrating a doping concentration of impurities taken along line S-S′ of FIG. 1.

Referring to FIGS. 1 and 2, an abrupt junction is formed at an interface between the protrusion portion 35 of the source layer 30 and the channel pattern 40. In detail, since the source layer 30 is epitaxially grown to be doped with impurities at a uniform concentration, a doping concentration of the impurities is rapidly changed in a boundary between the source layer 30 and the channel pattern 40 that is not doped with the impurities. Such an abrupt junction is formed at an interface between a portion of the layer-like structure of the source layer 30 adjacent to the protrusion portion 35 and the channel pattern 40, as well as at an interface between the protrusion portion 35 of the source layer 30 and the channel pattern 40. In addition, when the protrusion portion 35 has, for example, a columnar shape, the abrupt junction is formed at an interface between an upper surface of the protrusion portion 35 and the channel pattern 40 and an interface between the side surfaces of the protrusion portion 35 and the channel pattern 40.

In FIG. 2, the doping concentration of the source layer 30 is lower than the doping concentration of the channel pattern 40. However, this is to express that the source layer 30 and the drain pattern 50 are doped with different conductivity types. That is, when the source layer 30 is doped with n-type, the drain pattern 50 is doped with p-type, and vice versa. In particular, in FIG. 2, the source layer 30 has a predetermined doping concentration, and is doped with a conductive type different from that of the drain pattern 50, which is described as having a doping concentration in the (−) direction centered on the channel pattern 40.

The abrupt junction formed between the source layer 30 and the channel pattern 40 means that a profile of the doping concentration of the impurities at the interface is rapidly changed. When the abrupt junction is formed, a potential energy barrier is rapidly changed. When a bias is applied, the movement of carriers is facilitated, and thus an increase in the current amount may be induced.

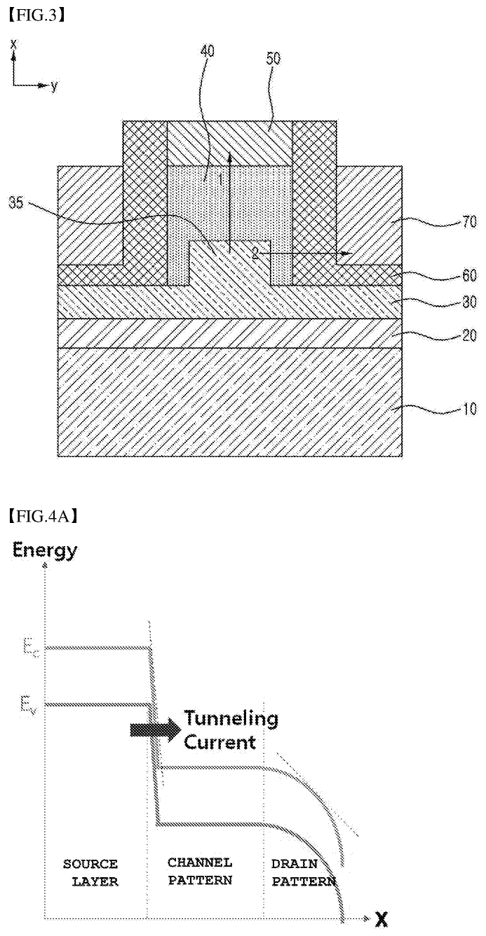

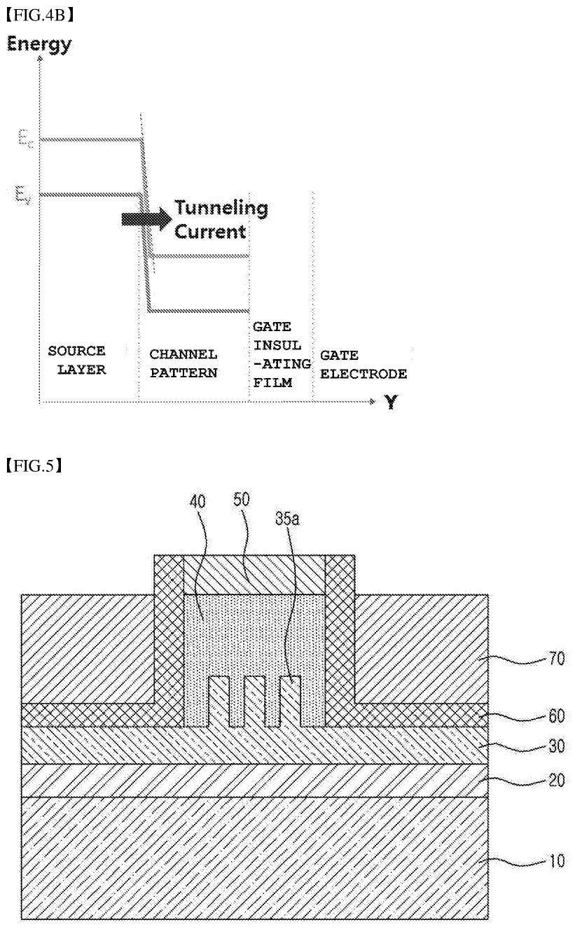

FIG. 3 is a cross-sectional view illustrating an operating principle of the vertical TFET according to an embodiment of the present invention. FIGS. 4A and 4B are graphs illustrating an energy band diagram and tunneling current from a source region of FIG. 3. FIGS. 4A and 4B respectively illustrate energy band diagrams in directions 1 and 2 of FIG. 3.

Referring to FIGS. 3 and 4A, in the energy band diagram in the direction 1 from the protrusion portion 35 of the source layer 30 to the channel pattern 40, an abrupt junction is formed between the source layer 30 and the channel pattern 40, and thus the width of a potential energy barrier between the source layer 30 and the channel pattern 40 may be greatly reduced. Thus, an amount of electrons performing band-to-band tunneling (BTBT) (the arrow of FIG. 4A) on a potential barrier during a driving operation of the TFET may be increased.

Referring to FIGS. 3 and 4B, it can be seen that, even in the energy band diagram in the direction 2 from the protrusion portion 35 of the source layer 30 to the channel pattern, an abrupt junction is formed between the source region and the channel pattern 40, and thus the width of a potential energy barrier between the source region and the channel pattern 40 may be greatly reduced. Thus, BTBT in a direction perpendicular to the substrate 10 from the protrusion portion 35 of the source layer 30, a direction parallel to the substrate 10, or combinations thereof may be increased.

As described above, considering that the contact area and the direction in which the tunneling phenomenon may occur are increased by an increase in the contact area between the source layer 30 and the channel pattern 40 due to the protrusion portion 35, as the possibility of tunneling caused by a decrease in the width of the potential barrier occurs is increased along with the increase in the area in which the tunneling phenomenon occurs, the drive current of the TFET may be significantly increased.

Referring again to FIGS. 1 and 2, the drain pattern 50 is disposed on the channel pattern 40 and overlaps the channel pattern 40. The drain pattern 50 is doped with impurities to have a concentration gradient. The drain pattern 50 may be formed by ion-implanting impurities into an upper region of the channel pattern 40. At this time, any one of the source layer 30 and the drain pattern 50 may be doped with n-type impurities, and the other may be doped with p-type impurities. For example, when the source region is doped with p-type impurities, the drain region may be doped with n-type impurities. Alternatively, when the source region is doped with n-type impurities, the drain region may be doped with p-type impurities.

Referring again to FIGS. 2 and 4A, a graded junction is formed at an interface between the drain pattern 50 and the channel pattern 40. That is, a doping concentration of impurities is gently changed at the interface between the drain pattern 50 and the channel pattern 40. To this end, the drain pattern 50 may be formed by ion-implanting impurities into the upper region of the channel pattern 40. The impurities with which the drain pattern 50 is doped by the ion-implanting may be distributed to have, for example, the Gaussian distribution. Since the doping concentration of the impurities of the drain region indicates the Gaussian distribution, the width of a potential energy barrier between the drain region and the channel pattern 40 is relatively widened such that the possibility of BTBT is reduced. Accordingly, the ambipolar current of the TFET may be reduced. That is, in the case of the graded junction, the effect of increasing the width of a tunneling barrier rather than changing the height of a potential barrier is caused, and tunneling of carriers such as electrons or formation of leakage current in an off state may be blocked.

In detail, conventional TFETs are in an off state at which electrons may hardly be tunneled since the width of a tunneling barrier between a source region and a channel region is wide when a gate voltage is low, and the conventional TFETs are in an on state at which it is sufficient for many electrons to be tunneled since the width of the tunneling barrier between the source region and the channel region is reduced when the gate voltage changes to a high positive (+) voltage. However, when the gate voltage changes to a high negative (−) voltage, an ambipolar leakage current phenomenon, in which tunneling current occurs since the width of a tunneling barrier between the channel region and a drain region is reduced, occurs.

In contrast, in the TFET according to the present invention, the graded junction is formed at the interface between the drain pattern 50 and the channel pattern 40, and as the doping concentration of the impurities of the drain pattern 50 has the Gaussian distribution, the width of the potential energy barrier between the drain pattern 50 and the channel pattern 40 is relatively widened such that, even when a gate voltage of the TFET is a high negative (−) voltage, the possibility of BTBT is reduced, thereby reducing ambipolar leakage current.

Referring again to FIG. 1, the gate insulating film 60 covers the source layer 30, the channel pattern 40, and the drain pattern 50. The gate insulating film 60 may cover the surface of the layer-like structure of the source layer 30 that is not covered by the channel pattern 40 and may cover at least partially the channel pattern 40 and the drain pattern 50 that are stacked on the protrusion portion 35. For example, the gate insulating film 60 may cover side surfaces of the channel pattern 40 and the drain pattern 50. The gate insulating film 60 may include an insulating material such as an oxide film, a nitride film, or the like.

The gate electrode 70 is disposed around the channel pattern 40 on the gate insulating film 60. The gate electrode 70 overlaps the channel pattern 40 in a horizontal direction on the gate insulating film 60. The height of the gate electrode 70 from the substrate 10 may be substantially the same as that of the channel pattern 40 from the substrate 10. That is, an upper surface of the gate electrode 70 may be coplanar with that of the channel pattern 40. According to an embodiment, the gate electrode 70 may have a double gate structure in which portions of the gate electrode are disposed opposite to each other with the channel pattern 40 as a center, have a triple gate structure which is disposed on three sides of the channel pattern (40) with the channel pattern 40 as a center, or have a gate-all-around structure which entirely surrounds the channel pattern 40.

FIG. 5 is a cross-sectional view of a vertical TFET according to another embodiment of the present invention.

Referring to FIG. 5, the vertical TFET according to the present embodiment is substantially the same as the TFET illustrated in FIG. 1, except for a protrusion portion 35a. Thus, the description of the same constituent components will be omitted.

In the present embodiment, a source layer 30 may have a plurality of protrusion portions 35a that protrude from a layer-like structure thereof. The protrusion portions 35a may have any three-dimensional shape such as a columnar shape, a horn shape, a hemispherical shape, or combinations thereof. In such a manner, the plurality of protrusion portions 35a are formed from the source layer 30, and thus a contact area between a channel pattern 40 and a source layer 30 may be significantly increased. The increase in the contact area between the channel pattern 40 and the source layer 30 may increase an area in which BTBT may be performed. Accordingly, the drive current of the TFET may be further increased than that of the TFET of FIG. 1.

Method of Fabricating Vertical TFET

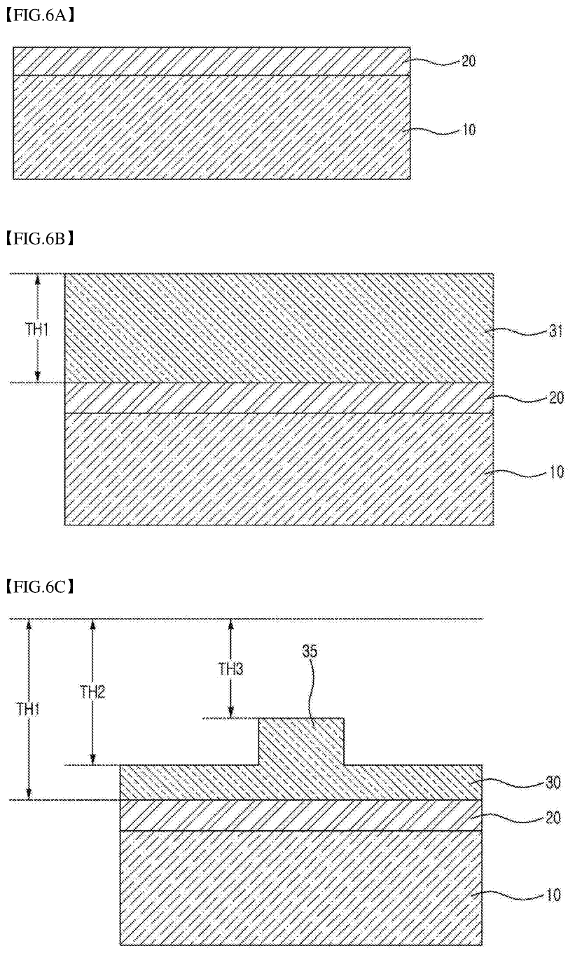

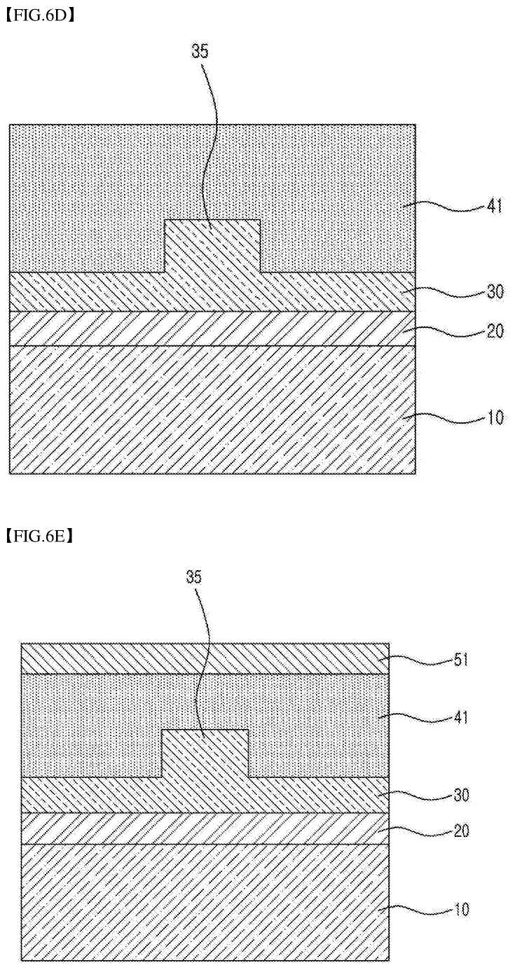

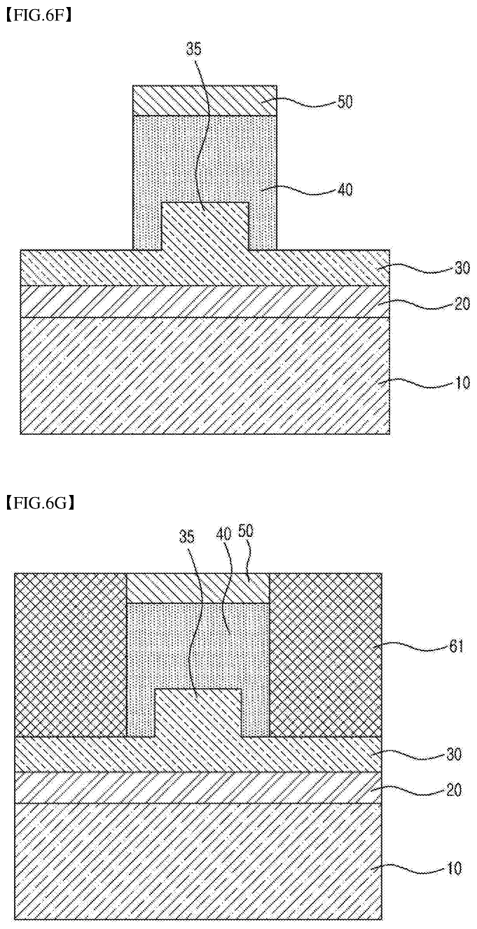

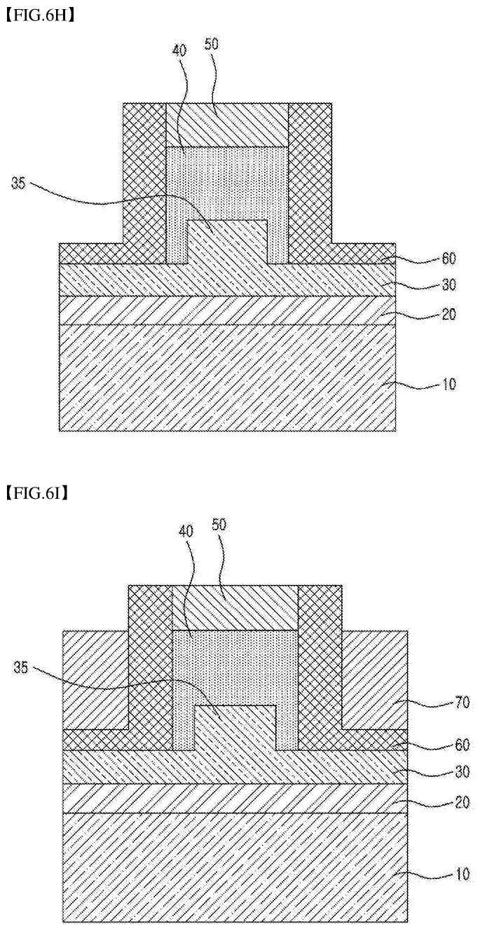

FIGS. 6A to 6I are cross-sectional views illustrating a method of fabricating a vertical TFET according to an embodiment of the present invention.

Referring to FIG. 6A, a buried oxide layer 20 is formed on a substrate 10. The substrate 10 is an insulating substrate and may include a material such as silicon or a polymer. The buried oxide layer 20 is disposed on the substrate 10 to protect an operating region of the TFET from defects such as oxygen ions but may also be omitted according to an embodiment.

Referring to FIG. 6B, a source layer 31 is epitaxially grown to a first thickness TH1 on the substrate 10 on which the buried oxide layer 20 is formed. The first thickness TH1 may range, for example, from 1 nm to 100 nm. The source layer 31 may be epitaxially grown on the substrate 10 by vapor phase epitaxy, liquid phase epitaxy, or molecular beam epitaxy. While the source layer 31 is epitaxially grown, the source layer 31 may be doped with n- or p-type impurities. Accordingly, the source layer 31 may be doped with impurities at a substantially uniform concentration in an entire region thereof.

Referring to FIG. 6C, the source layer 31 epitaxially grown to the first thickness TH1 is etched to form a source layer 30 that has a protrusion portion 35. At this time, the epitaxially grown source layer 31 may be etched to a second thickness TH2 less than the first thickness TH1 in the remainder thereof, except for a portion thereof in which the protrusion portion 35 is to be formed. The width of the formed protrusion portion 35 may range from 1 nm to 100 nm, the depth thereof may range from 1 nm to 50 nm, and the height thereof may range from 1 nm to 70 nm.

In such a manner, as the source layer 31 is etched from the remainder thereof, except for the portion thereof in which the protrusion portion 35 is to be formed, the protrusion portion 35 having, for example, a columnar shape, may be formed, but a three-dimensional shape of the protrusion portion 35 is not limited thereto. In addition, the source layer 31 may be further etched at least partially to a third thickness TH3 less than the second thickness TH2 even in the portion in which the protrusion portion 35 is to be formed. In addition, the source layer 31 may also be etched such that at least one protrusion portion 35 is formed. For example, the protrusion portion 35 formed by etching may include a plurality of protrusion shapes that protrude from the source layer 31.

Referring to FIG. 6D, a channel layer 41 is formed on the substrate 10 on which the protrusion portion 35 is formed. The channel layer 41 may cover the protrusion portion 35 of the source layer 30 and may further cover a portion of a layer-like structure of the source layer 30 that is adjacent to the protrusion portion 35. As the channel layer 41 is disposed on the source layer 30, an abrupt junction may be formed at an interface between the source layer 30 that includes the protrusion portion 35 and the channel layer 41.

Referring to FIG. 6E, impurities are ion-implanted into an upper region of the channel layer 41 to form a drain layer 51. The drain layer 51 may be doped with impurities by the ion-implanting to have a concentration gradient. For example, a doping concentration at which impurities are ion-implanted into the drain layer 51 may follow the Gaussian distribution. Accordingly, a graded junction may be formed at an interface between the drain layer 51 and the channel layer 41.

Referring to FIG. 6F, the channel layer 41 and the drain layer 51 are etched such that the protrusion portion 35 is covered, thereby forming a channel pattern 40 and a drain pattern 50. The channel layer 41 and the drain layer 51 are etched using one etching mask, thereby forming the channel pattern 40 and the drain pattern 50 that overlap each other.

Referring to FIGS. 60 and 6H, a gate insulating layer 61 is formed on the source layer 30, and the remainder of the gate insulating layer 61 is etched such that the channel pattern 40 and the drain pattern 50 having a vertical stack structure are covered, thereby forming a gate insulating film 60. The gate insulating film 60 may cover a surface of the layer-like structure of the source layer 30 that is exposed without being covered by the channel pattern 40, and side surfaces of the channel pattern 40 and the drain pattern 50. Although not illustrated, the gate insulating film 60 may further cover an upper surface of the drain pattern 50.

Referring to FIG. 6I, a gate electrode 70 is formed around the channel pattern 40 on the gate insulating film 60. The gate electrode 70 may be formed to have substantially the same height as that of the channel pattern 40 from the substrate 10. The gate electrode 70 may be formed with a double gate structure, a triple gate structure, or a gate-all-around structure around the channel pattern 40. For example, the gate electrode 70 may have a double gate structure in which portions of the gate electrode are disposed opposite to each other with the channel pattern 40 as a center, have a triple gate structure which is formed to surround three sides of the channel pattern 40, or have a gate-all-around structure which surrounds an entire region of the channel pattern 40.

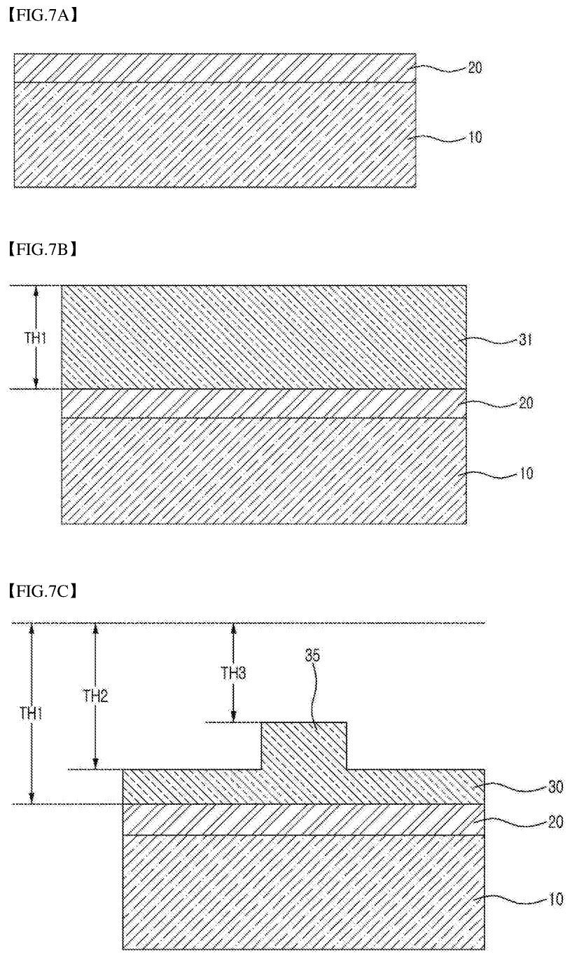

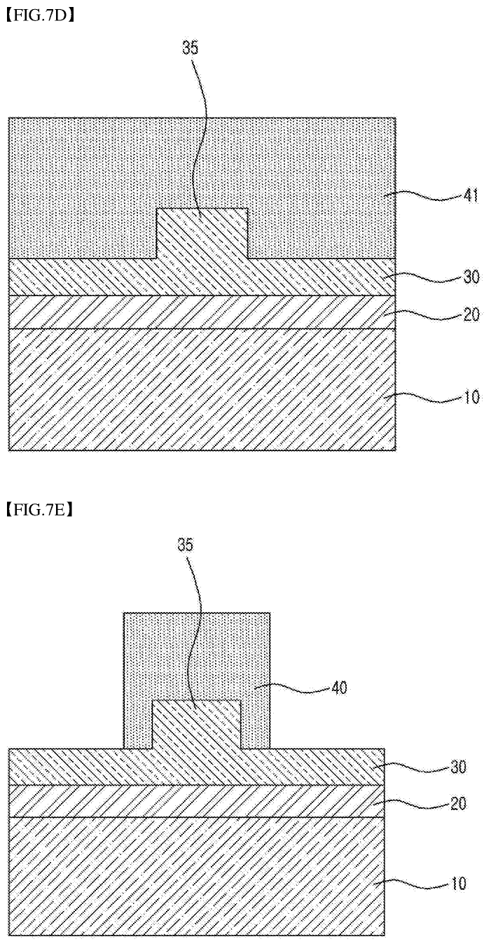

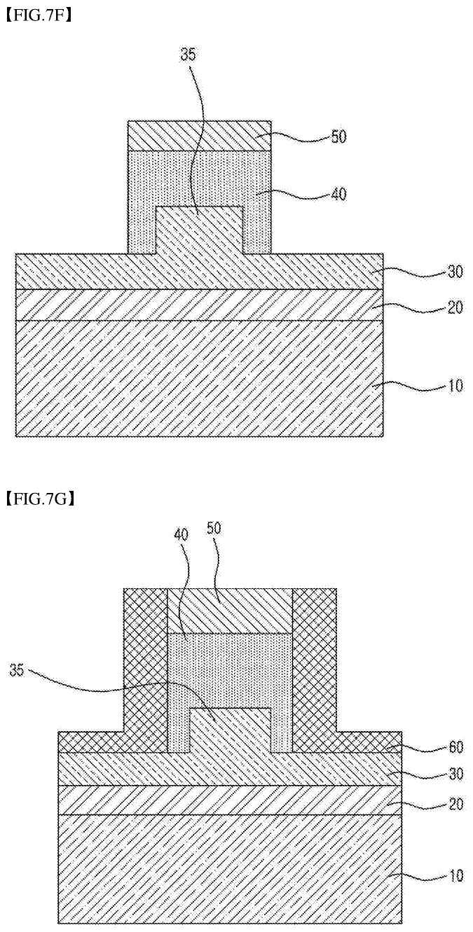

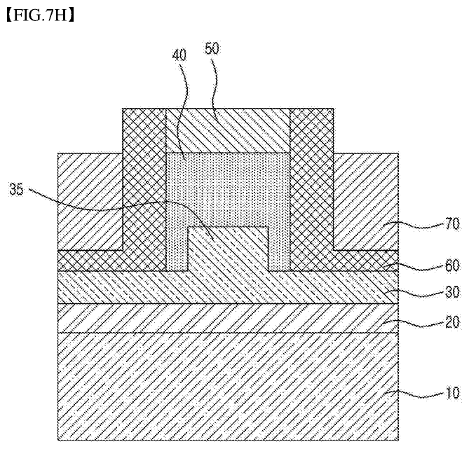

FIGS. 7A to 7H are cross-sectional views illustrating a method of fabricating a vertical TFET according to another embodiment of the present invention.

FIGS. 7A to 7H illustrate substantially the same as the fabricating method of FIGS. 6A to 6I, except for a process of forming the channel pattern 40 and the drain pattern 50. Thus, a detailed description of repeated processes will be omitted.

Referring to FIGS. 7A to 7D, a buried oxide layer 20 is formed on a substrate 10, and a source layer 30 having a protrusion portion 35 is formed on the buried oxide layer 20. A channel layer 41 is formed on the source layer 30 on which the protrusion portion 35 is formed.

Referring to FIG. 7E, the channel layer 41 is etched using an etching mask such that the protrusion portion 35 of the source layer 30 is covered, thereby forming a channel pattern 40. At this time, the channel pattern 40 may cover at least partially the protrusion portion 35 and a layer-like structure of the source layer 30 that is adjacent thereto.

Referring to FIG. 7F, impurities are ion-implanted into an upper region of the channel pattern 40 using a doping mask, thereby forming a drain pattern 50. The drain pattern 50 may be doped with impurities with the Gaussian distribution. Accordingly, a graded junction may be formed at an interface between the drain pattern 50 and the channel pattern 40.

Referring to FIGS. 7G and 7H, a gate insulating film 60 and a gate electrode 70 are formed on the substrate 10 on which the drain pattern 50 is formed.

As set forth above, according to the present invention, by epitaxially growing a source region, doping the source region with impurities at a uniform concentration, and forming an abrupt junction between the source region and a channel region, the width of a potential barrier between the source region and the channel region can be greatly reduced during a driving operation (on operation) of a TFET, thereby increasing an amount of electrons tunneled and increasing the drive current of the TFET.

Further, by forming the source region as a three-dimensional structure having a protrusion portion through etching the source region, an area in which tunneling occurs can be increased. Accordingly, a tunneling phenomenon in other directions as well as an epitaxial growth direction additionally occurs, thereby increasing the drive current of the TFET.

Moreover, by forming a drain region doped with a gentle concentration gradient by ion-implanting and forming a graded junction between the drain region and the channel region, the width of a potential barrier between the drain region and the channel region can be relatively widened. Accordingly, the ambipolar leakage current due to a gate voltage during an on or off operation of the TFET can be reduced.

Meanwhile, although embodiments according to the present invention disclosed in the specification and the drawings have been provided as specific examples for illustrative purposes, they should not be construed as limiting the scope of the present invention. It would be obvious to those skilled in the art that other modifications based on the technical idea of the present invention can be made, in addition to the embodiments disclosed herein.

1. A vertical tunneling field-effect transistor (TFET) comprising:
a source layer that is disposed on a substrate, has a protrusion portion extending upwardly, and is doped at a uniform concentration in an entire region thereof including the protrusion portion;
a channel pattern that covers the protrusion portion of the source layer on the source layer and exposes the remainder of the source layer;
a drain pattern that overlaps the channel pattern on the channel pattern and is doped to have a concentration gradient;
a gate insulating film that covers the source layer, the channel pattern, and the drain pattern; and
a gate electrode that is disposed around the channel pattern on the gate insulating film.

2. The vertical TFET of claim 1, wherein a junction between the protrusion portion of the source layer and the channel pattern is an abrupt junction, and a junction between the channel pattern and the drain pattern is a graded junction.

3. The vertical TFET of claim 1, wherein the protrusion portion has a three-dimensional shape that increases a contact area of the source layer with respect to the channel pattern.

4. The vertical TFET of claim 3, wherein the three-dimensional shape includes a columnar shape, a horn shape, a hemispherical shape, or combinations thereof.

5. The vertical TFET of claim 1, wherein a height of the gate electrode is the same as that of the channel pattern.

6. The vertical TFET of claim 1, wherein the gate electrode is disposed in a double gate, triple gate, or gate-all-around structure around the channel pattern.

7. The vertical TFET of claim 1, wherein the protrusion portion includes a plurality of protrusion shapes that protrude upwardly from the source layer.

8. A method of fabricating a vertical TFET, comprising:
epitaxially growing a source layer to a first thickness on a substrate;
forming, on the source layer, a protrusion portion protruding upwardly by etching the source layer to a second thickness less than the first thickness;
forming a channel pattern that covers the protrusion portion and a drain pattern that is ion-implanted into an upper region of the channel pattern, on the source layer in which the protrusion portion is formed;
forming a gate insulating film to cover the source layer, the channel pattern, and the drain pattern; and
forming a gate electrode on the gate insulating film to be disposed around the channel pattern.

9. The method of claim 8, wherein the epitaxially growing of the source layer includes doping the source layer with impurities at a uniform concentration.

10. The method of claim 9, wherein the source layer is epitaxially grown by vapor phase epitaxy, liquid phase epitaxy, or molecular beam epitaxy.

11. The method of claim 8, wherein the forming of the channel pattern and the drain pattern includes:
forming a channel layer on the source layer to cover the protrusion portion;
forming a drain layer by injecting impurities into an upper region of the channel layer by an ion implantation method; and
etching the channel layer and the drain layer such that the protrusion portion is covered.

12. The method of claim 8, wherein the forming of the channel pattern and the drain pattern includes:
forming a channel layer on the source layer to cover the protrusion portion;
forming the channel pattern by etching the channel layer such that the protrusion portion is covered; and
forming the drain pattern by ion-implanting impurities into the upper region of the channel pattern using a doping mask.

13. The method of claim 8, wherein the drain pattern is doped with impurities by the ion-implanting to have a concentration gradient.

14. The method of claim 8, wherein the forming of the protrusion portion includes etching the remainder of the source layer except for a portion thereof to the second thickness using an etching mask.
